(19) United States
(12) Patent Application Publication
(10) Pub. No.: US 2026/0189225 A1
(43) Pub. Date: Jul. 2, 2026

(54) ACTIVE DIODE CIRCUIT INCLUDING N-TYPE TRANSISTORS

(71) Applicants: Suhwan Kim, Portland, OR (US); Nachiket Desai, Portland, OR (US); Jingshu Yu, Hillsboro, OR (US); Harish K. Krishnamurthy, Beaverton, OR (US)

(72) Inventors: Suhwan Kim, Portland, OR (US); Nachiket Desai, Portland, OR (US); Jingshu Yu, Hillsboro, OR (US); Harish K. Krishnamurthy, Beaverton, OR (US)

(21) Appl. No.: 19/003,173

(22) Filed: Dec. 27, 2024

(51) Int. Cl. H03K 17/06; H03K 17/0416; H03K 17/30

(52) U.S. Cl. CPC H03K 17/063; H03K 17/04163; H03K 2017/307; H03K 2217/0063; H03K 2217/0072

(57) ABSTRACT

Some embodiments include an apparatus including a supply node; a bootstrap capacitor including first plate, and a second plate coupled to a circuit path, the circuit path coupled to a ground connection; and an active diode circuit. The active diode circuit includes an n-type transistor and a comparator. The n-type transistor includes a first terminal coupled to the supply node, a second terminal coupled to the first plate of the bootstrap capacitor, and a gate. The comparator includes a first input path coupled to the supply node, a second input path coupled to the first plate of the bootstrap capacitor, and an output node coupled the gate of the n-type transistor.

### BACKGROUND

Passive diodes a widely used in circuitry in many electronic devices. Some devices include components (e.g., transistors) that are formed gallium nitride (GaN) processes. Passive diodes are usually unavailable in many GaN processes that form analog circuitry such as bandgap circuit, bias current generation circuit, and bootstrap driver circuits. Passive diodes are useful in building bootstrap driver circuits in many high-voltage power-delivery applications where GaN devices are favored for their superior conductivity and fast switching capability. In a bootstrap driver circuit, a passive diode can be used as a single device that can operate to block a charging path to the bootstrap capacitor. However, as mentioned above, passive diodes often unavailable in many GaN processes. Thus, building a monolithic power stage with integrated bootstrap drivers including GaN devices becomes difficult. Moreover, p-type GaN devices often have poorer conductance than n-type GaN devices. Thus, implementing circuitry with n-type GaN devices without p-type (e.g., p-type GaN) devices can be more challenging.

### BRIEF DESCRIPTION OF THE DRAWINGS

FIG. 1A shows an apparatus including a bootstrap driver including an active diode circuit, according to some embodiments described herein.

FIG. 1B is a timing diagram showing waveforms of some of the signal of the bootstrap driver of FIG. 1A, according to some embodiments described herein.

FIG. 2 shows the active diode circuit of the bootstrap driver of FIG. 1A, according to some embodiments described herein.

FIG. 3 shows a driver circuit including bootstrap drivers, according to some embodiments described herein. shows an active bootstrap switch circuit of the voltage converter of FIG. 1A, according to some embodiments described herein.

FIG. 4A shows a power stage including high-side and low-side driver circuits, according to some embodiments described herein.

FIG. 4B is a timing diagram showing waveforms of some of the signal of the power stage FIG. 4A, according to some embodiments described herein.

FIG. 5 is a flow diagram of an example method of operating a bootstrap driver of an apparatus, according to some embodiments described herein.

FIG. 6 shows a block diagram of an example machine, according to some embodiments described herein.

FIG. 7 is a flow diagram of an example process of making an apparatus that includes an active diode circuit, according to some embodiments described herein.

### DETAILED DESCRIPTION

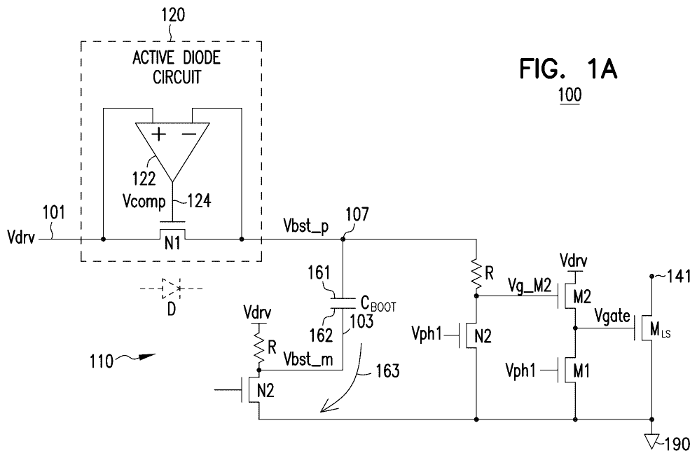

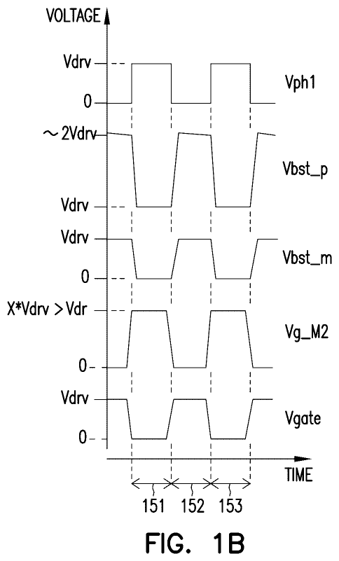

The techniques described herein involve a bootstrap driver that include an active diode circuit instead of a passive diode. In an example, the active diode circuit can include n-type GaN transistors without p-type transistors (e.g., without p-type GaN transistors). The described techniques provide a new way to implement an active diode circuit with n-type GaN devices (e.g., transistors) and resistors and open a possibility to build a monolithic and compact GaN-based power stage with an inclusion of a bootstrap driver. Further, incorporating the described bootstrap driver in power stage as described herein can improve performance and efficiency of the power stage. Moreover, the described techniques can also improve efficiency and reduce cost associated with implementing an active bootstrap circuit in circuitry including power stage in electronic devices and systems. These and other improvements and benefits of the described techniques are discussed in more detail below with reference to FIG. 1A through FIG. 7.

FIG. 1A shows a portion of an apparatus 100 including a bootstrap driver 110 that includes an active diode circuit 120, according to some embodiments described herein. Apparatus 100 can also include a transistor M_{LS} coupled to bootstrap driver 110. Apparatus 100 can include or be included in an electronic device or system, such as a computer (e.g., desktop, laptop, or notebook), a tablet, a cellular phone, a system on chip (SoC), a system in a package (SiP), or other electronic devices or systems. Bootstrap driver 110 and transistor M_{LS} can be part of a power stage (e.g., a voltage converter) of apparatus 100.

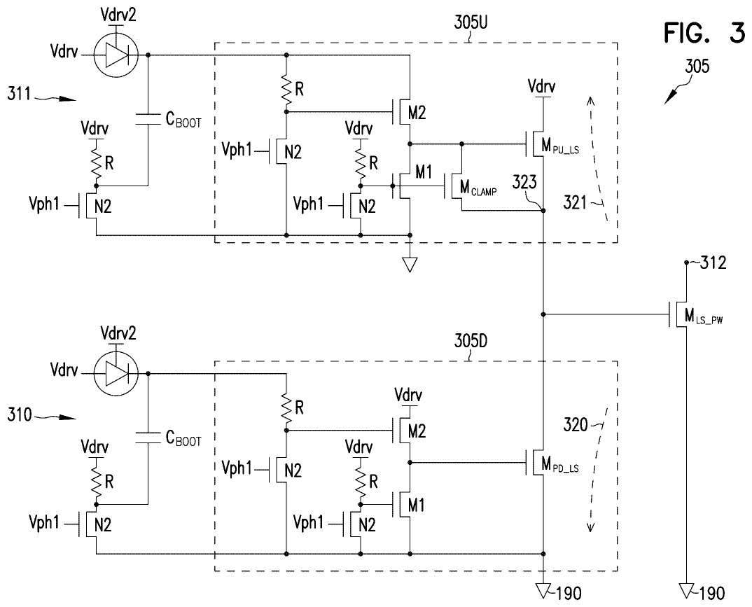

As shown in FIG. 1A, active diode circuit 120 can include a comparator 122 and a transistor N1. Besides active diode circuit 120, bootstrap driver 110 can also include transistors M1, M2, transistor N2, and M_{LS}, resistors R, and a bootstrap capacitor C_{BOOT} having plates (capacitor plates) 161 and 162. Plate 162 can be coupled to node 190 through a circuit path 163 (which can include on of transistors N2). Transistor M_{LS} can include a terminal (e.g., a drain) coupled to a node 141. FIG. 1A shows and transistor M_{LS} being part of bootstrap driver 110. However, transistor M_{LS} can be part of another circuit. In an example, bootstrap driver 110 can be part of a low-side driver circuit (e.g., driver circuit 305 in FIG. 3) of a low-side of a power stage. In such an example, node 141 can be coupled to a gate of transistor (e.g., transistor M_{LS_PW}) of the low-side driver circuit.

Bootstrap driver 110 can use transistor M1 to turn off transistor M_{LS} and transistor M2 to turn on transistor M_{LS}. Bootstrap driver 110 can be coupled to voltages (e.g., supply voltages) Vdrv and Vdrv2 at nodes (e.g., supply nodes) 101 and 102, respectively. Bootstrap driver 110 can also be coupled to node 190, which can be a ground connection or part of the ground connection of apparatus 100. Bootstrap driver 110 can receive signal (voltage signal) Vph1 to control (e.g., turn on or turn off) bootstrapping operation and transistor M_{LS} based on the values of signal Vph1. Sigal Vph1 can be provided by control circuitry (not shown) apparatus 100. Voltage Vdrv can also be called voltage signal Vdrv. Voltage Vdrv2 can also be called voltage signal Vdrv2. Vdrv and Vdrv2 can be generated by a voltage generator (not shown) of apparatus 100.

For simplicity, voltage Vdrv (or voltage signal Vdrv) is also called Vdrv (without the word “voltage” “or “signal”). Voltage Vdrv2 is also called Vdrv2 (without the word “voltage” “or “signal”). Signal Vph1 is also called Vph1 (without “signal”). In the same way for other voltages and signals described herein, the word “voltage” or “signal” is sometimes omitted for simplicity.

FIG. 1A also shows a diode D for purposes of comparing it with active diode circuit 120. Diode D is conventional passive diode (e.g., a discrete p-n diode). As shown in FIG. 1A, diode D can have an anode coupled to node 101 and a cathode coupled to node (voltage node) 107. Diode D can operate with other circuit elements of bootstrap driver 110 to provide bootstrapping operation in bootstrap driver 110, as discussed below.

In most of GaN process technologies, n-type GaN devices are used because p-type GaN devices have poor conductance. If p-type devices (e.g., p-type transistors) are available, in power-switch driver design, transistor M2 can be implemented with a p-type transistor, which will give a full voltage swing for signal (voltage signal) Vgate, as high as up to Vdrv. However, when p-type devices are not available, n-type devices (e.g., n-type transistors) can be used for transistor M2 as shown in FIG. 1A. In most situations, without bootstrapping operation, n-type transistor (like transistor M2) powered by Vdrv will only give (Vdrv−Vgs, not as high a up to Vdrv) to Vgate. Vgate having a value of Vdrv−Vgs will limit the conductance of transistor M_{LS}. In order to provide Vgate having a value as high as up to Vdrv to allow proper operation for transistor M_{LS}, bootstrap driver 110 is include apparatus to perform a bootstrapping operation. The bootstrapping operation generates a voltage (bootstrap voltage signal) Vbst_p at node 107 that is higher than (greater than) voltage Vdrv (e.g., close two times higher than Vdrv). The higher voltage (higher than Vdrv) causes a voltage Vg_M2 at the gate of transistor M2 to be at X*Vdrv, which is higher than Vdrv (Vg_M2=X*Vdrv>Vdrv). Symbol “*” indicates multiplication. Variable “X” can be greater than one (e.g., 1<X<2)). Vg_M2 being higher than Vdrv allows transistor M2 to properly drive M_{LS} with a full Vgate up to Vdrv. The following description describes operation of bootstrap driver 110 with diode D (without active diode circuit 120).

In operation, when Vph1 is at a value (e.g., high) to cause transistors N2 to turned on, voltage (voltage signal) Vbst_m at node 107 will be at a value (e.g., low) close to the voltage at node 190 (e.g., close to ground). This charges bootstrap capacitor C_{BOOT} up to (Vdrv−Vdiode) through diode D. Voltage Vdiode is a voltage drop across diode D. When Vph1 is at value (e.g., low) to cause transistors N2 to turn off, Vbst_m will rise to Vdrv, boosting Vbst_p at node 107 higher than Vdrv at node 101 and fully turn on transistor M2. This drives Vgate to Vdrv.

The above description of the bootstrapping operation is associated with the presence of diode D (without active diode circuit 120) being in bootstrap driver 110. In situations where diode D is not suitable for bootstrap driver 110 (e.g., the process of forming diode D is not compatible with the process of forming bootstrap driver 110), active diode circuit 120 (instead of diode D) is included in bootstrap driver 110. Active diode circuit 120 can operate to allow unidirectional charging to the bootstrap capacitor C_{BOOT}. However, active diode circuit 120 provides benefits of using n-type devices (e.g., n-type GaN devices) over diode D or other p-type devices. Further, another benefit of using active diode circuit instead of a passive diode is that as the voltage drop of the active diode circuit is usually much smaller than Vdiode (the voltage drop across a passive diode), the bootstrap capacitor can be charged fully up to Vdrv (not limited to Vdrv−Vdiode), generating a higher voltage to the gate.

The following description refers to bootstrap driver 110 having active diode circuit 120 instead of diode D. As shown in FIG. 1A, active diode circuit 120 can include transistor N1 having terminals (e.g., source and drain) coupled to nodes 101 and 107 (associated with Vdrv and Vbst_p, respectively). The gate of transistor N1 is couple to an output node 124 of comparator 122. Comparator 122 can operate to perform a comparison between Vdrv and Vbst_p and provide (e.g., generate) a comparison result based on the comparison result. The result comparison result is in the form of voltage represented by a voltage signal Vcomp at output node 124. The value of Vcomp is based on the values of Vdrv and Vbst_p. Comparator 122 can use Vcomp to control (e.g., turn on or turn off) transistor N1. For example, comparator 122 can provide (e.g., generate) Vcomp having one value (e.g., high) to turn on transistor N1 (to cause transistor N1 to conduct) in response to Vbst_p being lower than (less than) Vdrv (e.g., turn on transistor N1 when Vbst_p is lower than Vdrv). In another example, comparator 122 can provide Vcomp having another (e.g., low) to turn off transistor N1 (not to cause transistor N1 to conduct) in response to Vbst_p being higher than (greater than) Vdrv (e.g., turn off transistor N1 when Vbst_p is higher than Vdrv). Transistor N1 can include (e.g., can be) an n-type GaN transistor. Transistors M1, M2, transistor N2, and M_{LS} can also include (e.g., can be) an n-type GaN transistors. As described below, comparator 122 can also include devices (e.g., transistors) that are formed from n-type GaN devices.

FIG. 1B is a timing diagram showing example waveforms of some of the voltages and signals of FIG. 1A, according to some embodiments described herein. For simplicity, the waveforms for the voltages and signals in FIG. 1B are shown with the same timing axis. As shown in FIG. 1B, Vgate can have a range (can switch between) zero (e.g., ground) and Vdrv. Vg_M2 can have a range (can switch between) zero (e.g., ground) and X*Vdrv>Vdrv. Vph1 can have a range (can switch between) zero (e.g., ground) and Vdrv. Vbst_m can have a range (can switch between) zero (e.g., ground) and Vdrv. Vbst_p can have a range (can switch between) Vdrv and ˜2*Vdrv (symbol “˜” denotes approximately, e.g., within 5%). Thus, Vbst_p can switch from Vdrv to approximately two times Vdrv.

FIG. 1B shows time intervals (durations) 151, 152, and 153 that are measured in time unit (e.g., microsecond). As shown in FIG. 1B, during time interval 152, Vph1 can be provided with a relatively low voltage (e.g., 0V). This causes Vbst_p to change from Vdrv to 2*Vdrv during time interval 152. Vbst_m can be at Vdrv during time interval 152. During times intervals 151 and 153, Vph1 can be provided with a relatively high voltage (e.g., Vdrv). This causes Vbst_p to change (e.g., to discharge to) Vdrv during time intervals 151 and 153. Vbst_m can be at Vdrv during time interval 152.

In FIG. 1A, during time interval 152 of FIG. 1B, plate 161 of bootstrap capacitor C_{BOOT} (at node 107) is charged to 2*Vdrv. Plate 162 of bootstrap capacitor C_{BOOT} is charged to Vdrv. During time intervals 151 and 153, the plate 161 of bootstrap capacitor C_{BOOT} at node 107 is discharged to Vdrv. Plate of bootstrap capacitor C_{BOOT} at node 103 is discharged to 0V during time intervals 151 and 153. In FIG. 1A, transistor M_{LS} can be turned on during time interval 152 and turned off during time intervals 151 and 153.

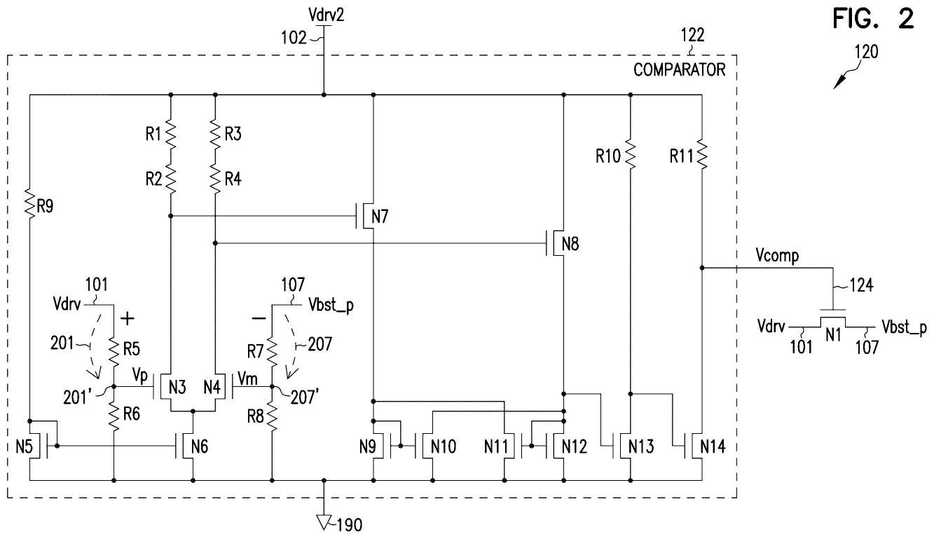

FIG. 2 shows active diode circuit 120 including comparator 122 and transistor N1 of FIG. 1A, according to some embodiments described herein. As shown FIG. 2, comparator 122 can include transistors N3 through N14 and resistors R1 through R11 coupled to each other and to transistor N1 in ways shown in FIG. 2. Transistors N3 through N14 can include (e.g., can be) n-type transistors. The n-type transistors can be n-type GaN transistors. As shown in FIG. 2, in comparator 122, resistors (e.g., resistors R1 through R11, instead of p-type transistors) are used to implement pull-up operations to Vdrv2. Thus, active diode circuit 120 can include n-type GaN transistors and resistors (e.g., resistors R1 through R11) without including p-type transistors.

As shown in FIG. 2, comparator 122 can include an input node “+” coupled to node 101 (associated with Vdrv) and an input node “-” coupled to node 107 (associated with Vbst_p). Comparator 122 can include input path (circuit path) 201 coupled between node 101 (which is coupled to input node “+”) and node 201′ (which is coupled to the gate of transistor N3). Comparator 122 can include input path (circuit path) 207 coupled between node 107 (which is coupled to input node “−” (which is coupled to the gate of transistor N4).

As shown in FIG. 2, input path 201 can include resistor R5 coupled between node 101 and node 201′. Input path 207 can include resistor R7 coupled between node 107 and node 207′. Comparator 122 can also include resistor R6 coupled between node 201′ and node 190, and resistor R8 coupled between node 207′ and node 190. Resistors R5 and R6 can form a resistor divider between node 101 and node 190. Resistors R7 and R8 can form a resistor divider between node 107 and node 190.

The values of resistors R5, R6, R7, and R8 can be selected such that the voltages at nodes 201′ and 207′ can be proportional to voltages Vdrv and Vbst_p, respectively. In FIG. 2, voltages Vp at node 201′ and Vm at node 207′ are proportional to Vdrv and Vbst_p, respectively. Thus, comparing Vp with Vm (performed by comparator 122) is equivalent to comparing Vdrv at node 101 with Vbst_p at node 107. Resistors R1, R2, R3, and R4 can have values, such that the resistance between node 102 and the drain of transistor N3 matches (e.g., is equal to) the resistance between nodes 102 and the drain of transistor N4. The matching in values improve accuracy in the comparison operation between Vdrv and Vbst_p.

In operation comparator 122 can perform a comparison to compare Vp and Vm (which are based on Vdrv and Vbst_p, respectively) and provide (e.g., generate) Vcomp based on the comparison. Comparator 122 uses Vcomp to transistor N1 to turn on or turn off transistor N1 as part of bootstrap operation of bootstrap driver 110 (FIG. 1A), as described in detail above with reference to FIG. 1A.

Improvements and benefits of the bootstrap driver (e.g., bootstrap driver 110) are mentioned above. For example, bootstrap driver 110 can provide possibility to build a monolithic and compact GaN-based power stage, improve performance and efficiency of the power stage, and improve efficiency and reduce cost associated with implementing an active bootstrap circuit.

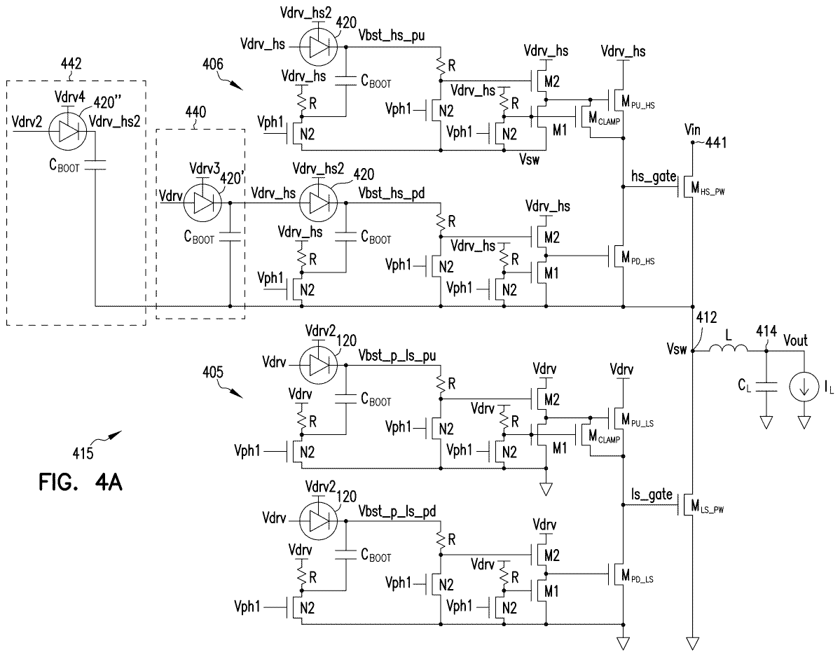

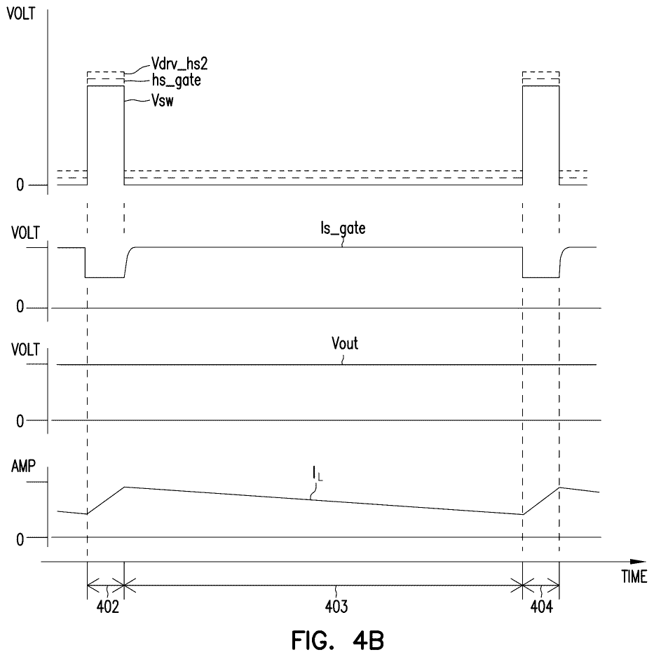

FIG. 3 shows a driver circuit 305 including bootstrap drivers 310 and 311, according to some embodiments described herein. In an example, driver circuit 305 can be a low-side driver circuit of a power stage (e.g., power stage 415 of FIG. 4A) associated with an apparatus (e.g., apparatus 100). As shown in FIG. 3, bootstrap drivers 310 can include a pull-down circuit 305D including a pull-down path 320. Bootstrap drivers 311 can include a pull-up circuit 305U including a pull-up path 321. Bootstrap drivers 310 and 311 have circuit elements similar to (or the same as) circuit elements of bootstrap driver 110 of FIG. 1A. For simplicity, description of similar (or the same) circuit elements and their operations are not repeated. As shown in FIG. 3, bootstrap driver 311 can include an additional transistor M_{CLAMP} to fully turn off transistor M_{PU_LS} because the source (at node 323) of transistor M_{PU_LS} is coupled to a variable voltage (unlike the source of transistors M_{PD_LS} that is coupled to a fixed potential (e.g., ground at node 190)).

As shown in FIG. 3, driver circuit 305 can include a transistor M_{PU_LS} in pull-up path 321, a transistor M_{PD_LS} in pull-down path 320, and a transistor M_{LS_PW}. The gate of transistor M_{LS_PW} is coupled to transistors M_{PU_LS} and M_{PD_LS} at node 323 (e.g., a shared node coupled to the source and drain of transistors M_{PU_LS} and M_{PD_LS}, respectively). Transistors M_{PU_LS}, M_{PD_LS}, M_{CLAMP} and M_{LS_PW} can include (e.g., can be) n-type GaN transistors.

In an example, driver circuit 305 can be part of low-side driver circuit (e.g., driver circuit 405 in FIG. 4A) of a power stage (e.g., power stage 415 of FIG. 4A). In such an example, node 312 can be coupled to an output path of the power stage.

In FIG. 3, driver circuit 305 can use bootstrap driver 311 and transistor M_{PU_LS} to operate to turn on transistor M_{LS_PW} (e.g., to couple node 312 to node 190 (ground connection)). Driver circuit 305 can operate to turn off transistor M_{LS_PW} using bootstrap driver 310 and transistor M_{PD_LS}.

As shown in FIG. 3, each of bootstrap drivers 310 and 311 can include an active diode circuit 120, which is described in details above with reference to FIG. 1A. Thus, driver circuit 305 (which includes bootstrap drivers 310 and 311) can have similar improvements and benefits like bootstrap driver 110 of FIG. 1A.

FIG. 4A shows a power stage 415 including driver circuits 405 and 406, according to some embodiments described herein. Power stage 415 can be an example of a half-bridge buck power stage to receive a voltage (e.g., input voltage) Vin at a node 441 and provide a voltage (e.g., output voltage) Vout. Driver circuits 405 and 406 can be called low-side driver circuit and high-side driver circuit, respectively, of power stage 415. The names low-side associated with driver circuit 405 and high-side associated with driver circuit 406 described herein are similar to conventional names low-side and high-side, respectively, associated with a power stage (like power stage 415) or a voltage regulator. For easy of viewing power stage 415 in FIG. 4A, voltages and signals associated with labels “ls_pu” and “ls_pd” refer to voltages and signals belong to the pull-up path and pull-down path, respectively, of driver circuit 405 of power stage 415. Voltages and signals associated with labels “hs_pu” and “hs_pd” refer to voltages and signals belong to the pull-up path and pull-down path, respectively, of driver circuit 406 of power stage 415. For example, as shown in FIG. 4A, in driver circuit 405, voltage Vbst_p_ls_pu refers to the bootstrap voltage on the pull-up path of driver circuit (low-side driver circuit) 405. In another example, voltage Vbst_p_hs_pu refers to the bootstrap voltage on the pull-up path of driver circuit (high-side driver circuit) 406.

As shown in FIG. 4A, driver circuit 405 can include a transistor M_{LS_PW} (which is included in the low-side of power stage 415). Driver circuit 406 can include a transistor M_{HS_PW} (which is included in the high-side of power stage 415). Transistors M_{HS_PW} and M_{LS_PW} can be controlled (e.g., turned on or turned off) by signals (voltage signals) hs_gate and ls_gate, respectively, at the gates of transistors M_{HS_PW} and M_{LS_PW}, respectively.

As shown in FIG. 4A, power stage 415 can include an output path coupled to a node (e.g., a switch node) 412, include an inductor L coupled to node 412, and a capacitor (e.g., a load capacitor) C_{L} coupled between inductor L and ground. Node 412 can provide a voltage Vsw. Power stage 415 can operate to provide a voltage Vout and a current (e.g., load current) I_{L} at a node 414. Vout and current I_{L} can be provided to a load (not shown) as supply voltage and current to the load.

As shown in FIG. 4A, each of driver circuits 405 and 406 include circuit elements similar to (or the same as) the circuit elements of driver circuit 305 of FIG. 3. For simplicity, description of similar (or the same) circuit elements and their operations are not repeated. As an example, driver circuit 406 can include transistors M_{PU_HS}, M_{PD_HS}, M_{CLAMP} and M_{HS_PW} that are similar to transistors M_{PU_LS}, M_{PD_LS}, M_{CLAMP}, and M_{LS_PW}, respectively, of driver circuit 405. Transistors M_{PU_HS}, M_{PD_HS}, M_{CLAMP} and M_{HS_PW} can include (e.g., can be) n-type GaN transistors.

As shown in FIG. 4A, driver circuit 406 can operate using voltages (supply voltages) Vdrv_hs and Vdrv_hs2. Vdrv_hs2 is higher than (greater than) Vdrv_hs (Vdrv_hs2>Vdrv_hs).

As shown in FIG. 4A, power stage 415 also includes voltage generators (supply voltage generators) 440 and 442 to generate voltages (shifting power supply voltages) Vdrv_hs and Vdrv_hs2, respectively, for driver circuit 406. Vdrv_hs and Vdrv_hs2 can be generated, such that Vdrv_hs=Vsw+Vdrv, and Vdrv_hs2=Vsw+Vdrv2.

As shown in FIG. 4A, voltage generators 440 and 442 can include respective active diode circuits 420, 420′, and 420″. Active diode circuits 420 can operate to allow driver circuit (e.g., high-side driver circuit) 406 to provide voltage Vbst_hs_pu and voltage Vbst_hs_pd based on Vdrv_hs and Vdrv_hs2.

Active diode circuits 420 can operate to allow driver circuit 406 to provide Vdrv_hs_pu and Vbst_hs_pd based on Vdrv_hs and Vdrv_hs2. Active diode circuits 420′ can operate to allow voltage generator 440 to generate Vdrv_hs based on Vdrv and Vdrv3. Active diode circuits 420″ can operate to allow voltage generator 442 to generate Vdrv_hs2 based on Vdrv2 and Vdrv4.

In FIG. 4A voltages (e.g., supply voltages) Vdrv, Vdr2, Vdrv3, and Vdrv4 can be provided to power stage 415 by a voltage generator (not shown) coupled to power stage 415. Vdrv4 is higher than (greater than) Vdrv3 (Vdrv3<Vdrv4). Vdrv3 is higher than Vdrv2 (Vdrv2<Vdrv3). Thus, in power stage 415, Vdrv<Vdrv2<Vdrv3<Vdrv4.

The relationship among Vdrv, Vdrv2, Vdrv3, and Vdrv4 can expressed as Vdrv2=A*Vdrv; Vdrv3=B*Vdrv; and Vdrv4=C*Vdrv, where each of the values A, B, and C is greater than one, and A<B<C. For example, A, B, and C can have values of 1.5, 2, and 2.5, respectively (an increment of 0.5 from A to B, and 0.5 from B to C). Thus, in this example, Vdrv2=1.5*Vdrv; Vdrv3=2*Vdrv; and Vdrv4=2.5*Vdrv. However, other increments can be used. For example, values A, B, and C can be 2, 3, and 4, respectively (an increment of 1.0 from A to B, and 1.0 from B to C). Thus, in this example, Vdrv2=2*Vdrv; Vdrv3 =3*Vdrv; and Vdrv4=4*Vdrv.

Similar to bootstrap driver 110 and driver circuit 305, the transistors in power stage 415 can formed from n-type GaN transistors and resistors, without p-type transistors and diodes (like diode D in FIG. 1A). Improvements and benefits of power stage can be similar to those of bootstrap driver 110 and driver circuit 305.

FIG. 4B is a timing diagram showing example waveforms of some of the voltages and signals of FIG. 4A, according to some embodiments described herein. For simplicity, the waveforms for the signals (voltage and current) in FIG. 4B are shown with the same timing axis. FIG. 4B shows time intervals (durations) 402, 403, and 404 that are measured in time unit (e.g., microsecond). As shown in FIG. 4B, during time intervals 402, 403, and 404, Vout can remain relatively unchanged. Current I_{L} can decrease during time interval 403 and increase during time intervals 402 and 404.

During time intervals 402 and 404, transistors M_{HS_PW} and M_{LS_PW} in FIG. 4A can turned on and turned off, respectively. This is in response signal hs_gate and ls_gate having levels (e.g., high and low, respectively) during time intervals 402 and 404, as shown in FIG. 4B. During time intervals 403, transistors M_{HS_PW} and M_{LS_PW} in FIG. 4A are turned off and turned on, respectively. This is in response signal hs_gate and ls_gate having levels (e.g., low and high, respectively) during time intervals 403, as shown in FIG. 4B.

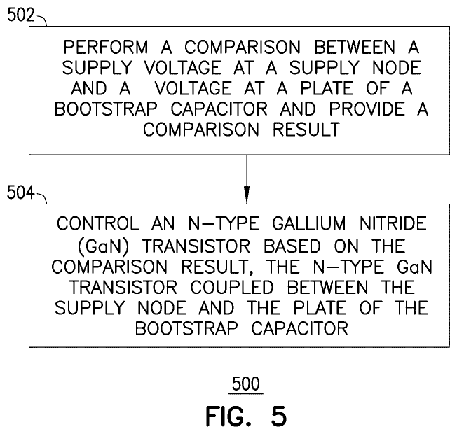

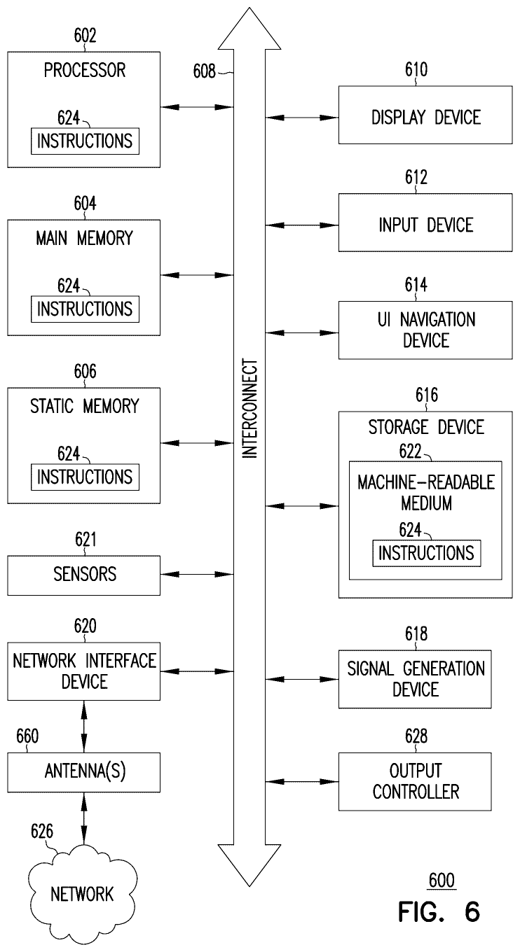

FIG. 5 is a flow diagram of an example method 500 of operating a bootstrap driver of an apparatus, according to some embodiments described herein. The apparatus associated with method 500 can include apparatus 100 of FIG. 1A. As shown in FIG. 5, method 500 can include operations 502 and 504, which may be executed by an embedded controller or another processor of a computing device (e.g., hardware processor 602 of machine 600 illustrated in FIG. 6, which can include one or more of the circuits discussed in connection with FIG. 1A through FIG. 4B. In some embodiments, one or more of the circuits discussed in connection with FIG. 1A through FIG. 4B can perform the functionalities (e.g., operations) shown in FIG. 5 and in the examples listed below.

In FIG. 5, operation 502 can include performing a comparison between a supply voltage (e.g., Vdrv) at a supply node of a driver circuit with a voltage (e.g., Vbst_p) at a plate of a bootstrap capacitor (e.g., C_{BOOT}), and providing a comparison result (e.g., Vcmp) based on the comparison. The comparison between the supply voltage and the voltage at the plate of the bootstrap capacitor can include (e.g., can be comparable to) comprising a first voltage (e.g., Vp) based on the supply voltage with a second voltage (e.g., Vm) based the voltage at the plate of a bootstrap capacitor.

Operation 504 can include controlling an n-type gallium nitride (GaN) transistor (e.g., N1) coupled between the plate of the bootstrap capacitor and the supply node based on the comparison result.

Method 500 can include fewer or more operations than the operations shown in FIG. 5. For example, method 500 can include operations of apparatus 100 including operations of bootstrap driver and driver circuits described above with reference to FIG. 1A through FIG. 4B. Method 500 can also include operations described in the examples listed below.

FIG. 6 shows a block diagram of an apparatus in the form of an example machine (e.g., an electronic system) 600 upon which any one or more of the techniques (e.g., methodologies) discussed herein may perform. In alternative embodiments, the machine 600 may operate as a standalone device or may be connected (e.g., networked) to other machines. In a networked deployment, machine 600 may operate in the capacity of a server machine, a client machine, or both in server-client network environments. In an example, machine 600 may function as a peer machine in a peer-to-peer (P2P) (or other distributed) network environment. The machine 600 may be a personal computer (PC), a tablet PC, a set-top box (STB), a personal digital assistant (PDA), a portable communications device, a mobile telephone, a smartphone, a web appliance, a network router, switch or bridge, or any other computing device capable of executing instructions (sequential or otherwise) that specify actions to be taken by that machine. Further, while only a single machine is shown, the term “machine” shall also be taken to include any collection of machines that individually or jointly execute a set (or multiple sets) of instructions to perform any one or more of the methodologies discussed herein, such as cloud computing, software as a service (SaaS), other computer cluster configurations. The terms “machine,” “computing device,” and “computer system” are used interchangeably.

The apparatus including machine 600 may be configured to perform one or more of the methods and/or operations disclosed herein. The apparatus may be intended as a component of machine 600 to perform one or more of the methods and/or operations disclosed herein and/or to perform a portion of one or more of the methods and/or operations disclosed herein. In some embodiments, the apparatus may include a pin or other means to receive power. In some embodiments, the apparatus may include power conditioning hardware.

Machine (e.g., computer system) 600 may include a hardware processor 602 (e.g., a central processing unit (CPU), a graphics processing unit (GPU), a hardware processor core, or any combination thereof), a main memory 604, and a static memory 606, some or all of which may communicate with each other via an interconnect (e.g., bus) 608. In some aspects, main memory 604, static memory 606, or any other type of memory (including cache memory) used by machine 600 can be configured based on the disclosed techniques or can implement the disclosed memory devices.

Specific examples of main memory 604 include Random Access Memory (RAM) and semiconductor memory devices, which may include, in some embodiments, storage locations in semiconductors such as registers. Specific examples of static memory 606 include non-volatile memory, such as semiconductor memory devices (e.g., Electrically Programmable Read-Only Memory (EPROM), Electrically Erasable Programmable Read-Only Memory (EEPROM)) and flash memory devices; magnetic disks, such as internal hard disks and removable disks; magneto-optical disks; RAM; and CD-ROM and DVD-ROM disks.

Machine 600 may further include a display device 610, an input device 612 (e.g., a keyboard), and a user interface (UI) navigation device 614 (e.g., a mouse). In an example, display device 610, input device 612, and UI navigation device 614 may be a touchscreen display. The machine 600 may additionally include a storage device (e.g., drive unit or another mass storage device) 616, a signal generation device 618 (e.g., a speaker), a network interface device 620, and one or more sensors 621, such as a global positioning system (GPS) sensor, compass, accelerometer, or other sensors. Machine 600 may include an output controller 628, such as a serial (e.g., universal serial bus (USB), parallel, or other wired or wireless (e.g., infrared (IR), near field communication (NFC), etc.) connection to communicate or control one or more peripheral devices (e.g., a printer, card reader, etc.). In some embodiments, hardware processor 602 and/or instructions 624 may comprise processing circuitry and/or transceiver circuitry.

Storage device 616 may include a machine-readable medium 622 on which one or more sets of data structures or instructions 624 (e.g., software) embodying or utilized by any one or more of the techniques or functions described herein can be stored. Instructions 624 may also reside, completely or at least partially, within the main memory 604, within static memory 606, or hardware processor 602 during execution thereof by machine 600. In an example, one or any combination of hardware processor 602, main memory 604, static memory 606, or storage device 616 may constitute machine-readable media.

Specific examples of machine-readable media may include non-volatile memory, such as semiconductor memory devices (e.g., EPROM or EEPROM) and flash memory devices; magnetic disks, such as internal hard disks and removable disks; magneto-optical disks; RAM; and CD-ROM and DVD-ROM disks.

FIG. 6 shows the machine-readable medium 622 as a single medium as an example. However, the term “machine-readable medium” may include a single medium or multiple media (e.g., a centralized or distributed database and/or associated caches and servers) configured to store instructions 624.

The term “machine-readable medium” may include any medium that is capable of storing, encoding, or carrying instructions for execution by machine 600 and that causes machine 600 to perform any one or more of the techniques of the present disclosure or that is capable of storing, encoding, or carrying data structures used by or associated with such instructions. Non-limiting machine-readable medium examples may include solid-state memories and optical and magnetic media. Specific examples of machine-readable media may include non-volatile memory, such as semiconductor memory devices (e.g., Electrically Programmable Read-Only Memory (EPROM), Electrically Erasable Programmable Read-Only Memory (EEPROM)) and flash memory devices; magnetic disks, such as internal hard disks and removable disks; magneto-optical disks; Random Access Memory (RAM); and CD-ROM and DVD-ROM disks. In some examples, machine-readable media may include non-transitory machine-readable media. In some examples, machine-readable media may include machine-readable media that is not a transitory propagating signal.

Instructions 624 may further be transmitted or received over a communications network 626 using a transmission medium via network interface device 620 utilizing any one of several transfer protocols (e.g., frame relay, internet protocol (IP), transmission control protocol (TCP), user datagram protocol (UDP), hypertext transfer protocol (HTTP), etc.). Example communication networks may include a local area network (LAN), a wide area network (WAN), a packet data network (e.g., the Internet), mobile telephone networks (e.g., cellular networks), Plain Old Telephone (POTS) networks, and wireless data networks (e.g., Institute of Electrical and Electronics Engineers (IEEE) 302.11 family of standards known as Wi-Fi®, IEEE 302.16 family of standards known as WiMax®), IEEE 302.8.4 family of standards, a Long Term Evolution (LTE) family of standards, a Universal Mobile Telecommunications System (UMTS) family of standards, peer-to-peer (P2P) networks, among others.

In an example, network interface device 620 may include one or more physical jacks (e.g., Ethernet, coaxial, or phone jacks) or one or more antennas to connect to communications network 626. In an example, network interface device 620 may include a connector, in which the connector conforms with at least one of USB, High-Definition Multimedia Interface (HDMI), Thunderbolt, Peripheral Component Interconnect Express (PCIe), Ethernet, and Fiber Optic specifications. In an example, network interface device 620 may include one or more antennas 660 to wirelessly communicate using at least one single-input multiple-output (SIMO), multiple-input multiple-output (MIMO), or multiple-input single-output (MISO) techniques. In some examples, network interface device 620 may wirelessly communicate using multiple-user MIMO techniques. The term “transmission medium” shall be taken to include any intangible medium that can store, encode, or carry instructions for execution by machine 600 and includes digital or analog communications signals or other intangible media to facilitate communication of such software.

Examples, as described herein, may include, or may operate on, logic or several components, modules, or mechanisms. Modules are tangible entities (e.g., hardware) capable of performing specified operations and may be configured or arranged in a particular manner. In an example, circuits may be arranged (e.g., internally or concerning external entities such as other circuits) in a specified manner as a module. In an example, the whole or part of one or more computer systems (e.g., a standalone, client, or server computer system) or one or more hardware processors may be configured by firmware or software (e.g., instructions, an application portion, or an application) as a module that operates to perform specified operations. In an example, the software may reside on a machine-readable medium. In an example, the software, when executed by the underlying hardware of the module, causes the hardware to perform the specified operations.

Accordingly, the term “module” is understood to encompass a tangible entity, be that an entity that is physically constructed, specifically configured (e.g., hardwired), or temporarily (e.g., transitorily) configured (e.g., programmed) to operate in a specified manner or to perform part, all, or any operation described herein. Considering examples in which modules are temporarily configured, each of the modules need not be instantiated at any one moment in time. For example, where the modules comprise a general-purpose hardware processor configured using the software, the general-purpose hardware processor may be configured as respective different modules at separate times. The software may accordingly configure a hardware processor, for example, to constitute a particular module at one instance of time and to constitute a different module at a different instance of time.

Some embodiments may be implemented fully or partially in software and/or firmware. This software and/or firmware may take the form of instructions contained in or on a non-transitory computer-readable storage medium. Those instructions may then be read and executed by one or more processors to enable the performance of the operations described herein. The instructions may be in any suitable form, such as but not limited to source code, compiled code, interpreted code, executable code, static code, dynamic code, and the like. Such a computer-readable medium may include any tangible non-transitory medium for storing information in a form readable by one or more computers, such as but not limited to read-only memory (ROM), random access memory (RAM), magnetic disk storage media, optical storage media, flash memory, etc.

The above-detailed description includes references to the accompanying drawings, which form a part of the detailed description. The drawings show, by way of illustration, specific embodiments that may be practiced. These embodiments are also referred to herein as “examples.” Such examples may include elements in addition to those shown or described. However, examples that include the elements shown or described are also contemplated. Moreover, also contemplated are examples using any combination or permutation of those elements shown or described (or one or more aspects thereof), either with respect to a particular example (or one or more aspects thereof) or with respect to other examples (or one or more aspects thereof) shown or described herein.

The embodiments as described above may be implemented in various hardware configurations that may include a processor for executing instructions that perform the techniques described. Such instructions may be contained in a machine-readable medium such as a suitable storage medium or a memory or other processor-executable medium.

The embodiments as described herein may be implemented in several environments, such as part of an IC chip, a system (e.g., a system in the form of machine 600, a system on chip, a system-in-package, a system-on-package, or a combination of these systems), a set of intercommunicating functional blocks, or similar, although the scope of the disclosure is not limited in this respect.

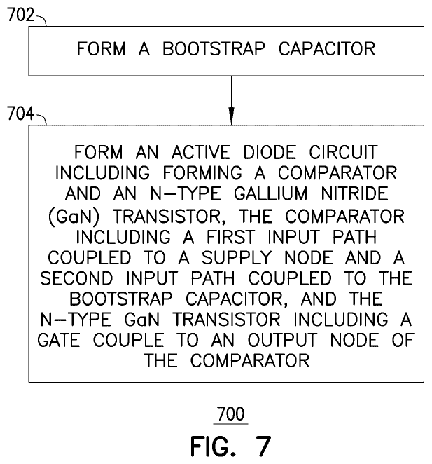

FIG. 7 is a flow diagram of an example process 700 that includes a process of making an apparatus that includes an active diode circuit, according to some embodiments described herein. The apparatus associated with process 700 can include apparatus 100 of FIG. 1A or machine 600 of FIG. 6. The active diode circuit associated with process 700 can include any of the active diode circuit (e.g., active diode circuits 120, 420, 420′and 420″ described above with reference to FIG. 1A through FIG. 4B.

As shown in FIG. 7, process 700 can include activities 702 and 704. Activity 702 can include forming a bootstrap capacitor. Activity 704 can include forming an active diode circuit, including forming a comparator and an n-type Gallium nitride (GaN) transistor. The comparator includes a first input path coupled to a supply node and a second input path coupled to the bootstrap capacitor. The n-type GaN transistor includes a gate coupled to an output node of the comparator.

Activities 702 and 704 can be performed in an order different from the order shown in FIG. 7. Process 700 can include fewer or more activities than the activities shown in FIG. 7. For example, process 700 can include forming other elements of the apparatus including elements of a bootstrap driver and driver circuits described above with reference to FIG. 1A through FIG. 4B. Process 700 can also include activities described in the examples listed below.

In the detailed description and the claims, the term “on” used with respect to two or more elements (e.g., materials), one “on” the other, means at least some contact between the elements (e.g., between the materials). The term “over” means the elements (e.g., materials) are in close proximity, but possibly with one or more additional intervening elements (e.g., materials) such that contact is possible but not required. Neither “on” nor “over” implies any directionality as used herein unless stated as such.

In the detailed description and the claims, the term “adjacent” generally refers to a position of a thing being next to (e.g., either immediately next to or close to with one or more things between them) or adjoining another thing (e.g., abutting it or contacting it (e.g., directly coupled to) it).

In the detailed description and the claims, the terms “first”, “second”, and “third,” etc. are used merely as labels, and are not intended to impose numerical requirements on their objects.

In the detailed description and the claims, a list of items joined by the term “at least one of” can mean any combination of the listed items. For example, if items A and B are listed, then the phrase “at least one of A and B” means A only; B only; or A and B. In another example, if items A, B, and C are listed, then the phrase “at least one of A, B and C” means A only; B only; C only; A and B (excluding C); A and C (excluding B); B and C (excluding A); or all of A, B, and C. Item A can include a single element or multiple elements. Item B can include a single element or multiple elements. Item C can include a single element or multiple elements.

In the detailed description and the claims, a list of items joined by the term “one of” can mean only one of the list items. For example, if items A and B are listed, then the phrase “one of A and B” means A only (excluding B), or B only (excluding A). In another example, if items A, B, and C are listed, then the phrase “one of A, B and C” means A only; B only; or C only. Item A can include a single element or multiple elements. Item B can include a single element or multiple elements. Item C can include a single element or multiple elements.

Described implementations of the subject matter can include one or more features, alone or in combination, as illustrated below by way of examples.

Example 1 is an electronic apparatus comprising a supply node, a bootstrap capacitor including first plate, and a second plate coupled to a circuit path, the circuit path coupled to a ground connection, and an active diode circuit including an n-type transistor including a first terminal coupled to the supply node, a second terminal coupled to the first plate of the bootstrap capacitor, and a gate, and a comparator including a first input path coupled to the supply node, a second input path coupled to the first plate of the bootstrap capacitor, and an output node coupled the gate of the n-type transistor.

In Example 2, the subject matter of Example 1 includes subject matter wherein the n-type transistor includes a gallium-nitride (GaN) transistor.

In Example 3, the subject matter of Examples 1-2 includes subject matter wherein the comparator includes a first n-type transistor and a second n-type transistor, and wherein the first input path includes a first resistor coupled between a gate of the first n-type transistor and the supply node, and the second input path includes a second resistor coupled between a gate of the second n-type transistor and the first plate of the bootstrap capacitor.

In Example 4, the subject matter of Example 3 includes subject matter wherein the first input path includes a first additional resistor coupled between the gate of the first n-type transistor and a ground connection, and the second input path includes a second additional resistor coupled between the gate of the second n-type transistor and the ground connection.

In Example 5, the subject matter of Example 3 includes subject matter wherein the first n-type transistor and the second n-type transistor are n-type gallium-nitride (GaN) transistors.

In Example 6, the subject matter of Examples 1-5, further comprising a first additional n-type transistor including a gate coupled to the first plate of the bootstrap capacitor, a first terminal coupled to the supply node, and a second terminal, a second additional n-type transistor including a gate to receive a voltage signal, a first terminal coupled to the second terminal of the first additional n-type transistor, and a second terminal coupled to a ground connection, and a third additional n-type transistor including a gate coupled to the first terminal of the second additional n-type transistor.

In Example 7, the subject matter of Example 6 includes subject matter wherein the first additional n-type transistor, the second additional n-type transistor, and the third additional n-type transistor are gallium-nitride (GaN) transistors.

In Example 8, the subject matter of Examples 1-7 includes subject matter wherein the circuit path includes an n-type transistor coupled between the second plate of the bootstrap capacitor and the ground connection.

In Example 9, the subject matter of Examples 1-8 comprises a system-on-chip (SoC), the SoC comprising the bootstrap capacitor and the active diode circuit.

In Example 10, the subject matter of Examples 1-8, further comprising a connector and an integrated circuit (IC) chip coupled to the connector, the IC chip including the bootstrap capacitor and the active diode circuit, wherein the connector conforms with at least one of Universal Serial Bus (USB), High-Definition Multimedia Interface (HDMI), Thunderbolt, Peripheral Component Interconnect Express (PCIe), Ethernet, and Fiber Optic specifications.

Example 11 is an electronic apparatus comprising a supply node, a first bootstrap capacitor, a first active diode circuit including a first n-type Gallium nitride (GaN) transistor coupled to the supply node and the first bootstrap capacitor, a second bootstrap capacitor, a second active diode circuit including a second n-type GaN transistor coupled to the supply node and the second bootstrap capacitor, a pull-up circuit coupled to the first bootstrap capacitor, a pull-down circuit coupled to the second bootstrap capacitor, and a third transistor including a gate coupled to the pull-up circuit and the pull-down circuit.

In Example 12, the subject matter of Example 11 includes subject matter wherein the first active diode circuit includes a first comparator including a first input path coupled to the supply node, a second input path coupled to the first bootstrap capacitor, and an output node coupled to a gate of the first n-type GaN transistor, and the second active diode circuit includes a second comparator including a first additional input path coupled to the supply node, a second additional input path coupled to the second bootstrap capacitor, and an additional output node coupled to a gate of the second n-type GaN transistor.

In Example 13, the subject matter of Examples 11-12 includes subject matter wherein the pull-up circuit includes a first additional transistor coupled between the supply node and the gate of the third transistor, and the pull-down circuit includes a second additional transistor coupled between the gate of the third transistor and a ground connection.

In Example 14, the subject matter of Examples 11-13, further comprising a first additional bootstrap capacitor, a first additional active diode circuit including a first additional n-type GaN transistor coupled to the supply node and the first additional bootstrap capacitor, a second additional bootstrap capacitor, a second additional active diode circuit including a second additional n-type GaN transistor coupled to the supply node and the second additional bootstrap capacitor, an additional pull-up circuit coupled to the first additional bootstrap capacitor, an additional pull-down circuit coupled to the second additional bootstrap capacitor, and a fourth transistor including a gate coupled to the additional pull-up circuit and the additional pull-down circuit, and a terminal coupled to a terminal of the third transistor.

In Example 15, the subject matter of Example 14, further comprising an inductor coupled to the terminal of third transistor and the terminal of the fourth transistor.

In Example 16, the subject matter of Examples 14-15 comprises a power stage, and wherein the third transistor is included in a low-side of the power stage, and the fourth transistor is included in a high-side transistor of the power stage.

In Example 17, the subject matter of Examples 14-16, further comprising a first additional capacitor coupled between a voltage node and a ground connection, and third additional active diode circuit coupled to the supply node and the voltage node.

In Example 18, the subject matter of Examples 11-17 comprises as system in a package (SiP), the SiP including the first bootstrap capacitor, the first active diode circuit, the second bootstrap capacitor, the second active diode circuit, the pull-up circuit, the pull-down circuit, and the third transistor.

Example 19 is a process of making an electronic apparatus, comprising forming a bootstrap capacitor, and forming an active diode circuit, including forming a comparator and an n-type Gallium nitride (GaN) transistor, the comparator including a first input path coupled to a supply node and a second input path coupled to the bootstrap capacitor, and the n-type GaN transistor including a gate coupled to an output node of the comparator.

In Example 20, the subject matter of Example 19 includes subject matter wherein forming the comparator and the n-type GaN transistor includes coupling a first terminal of the n-type GaN transistor to the supply node, and coupling a second terminal of the n-type GaN transistor to a plate of the capacitor.

Example 21 is a method of operating a bootstrap driver of electronic apparatus, comprising performing a comparison between a supply voltage at a supply node of a driver circuit with a voltage at a plate of a bootstrap capacitor, and providing a comparison result based on the comparison, and controlling an n-type gallium nitride (GaN) transistor based on the comparison result, the n-type GaN transistor coupled between the plate of the bootstrap capacitor and the supply node.

In Example 22, the subject matter of Example 21 includes subject matter wherein controlling the n-type GaN transistor includes turning on the n-type GaN transistor in response to the supply voltage being greater than the voltage at the plate of the bootstrap capacitor, and turning off the n-type GaN transistor in response to the first voltage being less than the second voltage.

Example 23 is an apparatus comprising at least one machine-readable medium including instructions that, when executed by processing circuitry, cause the processing circuitry to perform operations to implement any of Examples 1-22.

Example 24 is an apparatus comprising means to implement any of Examples 1-22.

Example 25 is a system to implement any of Examples 1-22.

Example 26 is a method to implement any of Examples 1-22.

The above description and the drawings illustrate some embodiments of the inventive subject matter to enable those skilled in the art to practice the embodiments of the inventive subject matter. Other embodiments may incorporate structural, logical, electrical, process, and other changes. Examples merely typify possible variations. Portions and features of some embodiments may be included in, or substituted for, those of others. Many other embodiments will be apparent to those of skill in the art upon reading and understanding the above description.

The Abstract is provided to allow the reader to ascertain the nature and gist of the technical disclosure. It is submitted with the understanding that it will not be used to limit or interpret the scope or meaning of the claims. The following claims are hereby incorporated into the detailed description, with each claim standing on its own as a separate embodiment.

What is claimed is:

1. An apparatus comprising:
a supply node;
a bootstrap capacitor including first plate, and a second plate coupled to a circuit path, the circuit path coupled to a ground connection; and
an active diode circuit including:
an n-type transistor including a first terminal coupled to the supply node, a second terminal coupled to the first plate of the bootstrap capacitor, and a gate; and
a comparator including a first input path coupled to the supply node, a second input path coupled to the first plate of the bootstrap capacitor, and an output node coupled the gate of the n-type transistor.

2. The apparatus of claim 1, wherein the n-type transistor includes a gallium-nitride (GaN) transistor.

3. The apparatus of claim 1, wherein the comparator includes a first n-type transistor and a second n-type transistor, and wherein:
the first input path includes a first resistor coupled between a gate of the first n-type transistor and the supply node; and
the second input path includes a second resistor coupled between a gate of the second n-type transistor and the first plate of the bootstrap capacitor.

4. The apparatus of claim 3, wherein:
the first input path includes a first additional resistor coupled between the gate of the first n-type transistor and a ground connection; and
the second input path includes a second additional resistor coupled between the gate of the second n-type transistor and the ground connection.

5. The apparatus of claim 3, wherein the first n-type transistor and the second n-type transistor are n-type gallium-nitride (GaN) transistors.

6. The apparatus of claim 1, further comprising:
a first additional n-type transistor including a gate coupled to the first plate of the bootstrap capacitor, a first terminal coupled to the supply node; and a second terminal;
a second additional n-type transistor including a gate to receive a voltage signal, a first terminal coupled to the second terminal of the first additional n-type transistor, and a second terminal coupled to a ground connection; and
a third additional n-type transistor including a gate coupled to the first terminal of the second additional n-type transistor.

7. The apparatus of claim 6, wherein the first additional n-type transistor, the second additional n-type transistor, and the third additional n-type transistor are gallium-nitride (GaN) transistors.

8. The apparatus of claim 1, wherein the circuit path includes an n-type transistor coupled between the second plate of the bootstrap capacitor and the ground connection.

9. The apparatus of claim 1, wherein the apparatus comprises a system-on-chip (SoC), the SoC comprising the bootstrap capacitor and the active diode circuit.

10. The apparatus of claim 1, further comprising a connector and an integrated circuit (IC) chip coupled to the connector, the IC chip including the bootstrap capacitor and the active diode circuit, wherein the connector conforms with at least one of Universal Serial Bus (USB), High-Definition Multimedia Interface (HDMI), Thunderbolt, Peripheral Component Interconnect Express (PCIe), Ethernet, and Fiber Optic specifications.

11. An apparatus comprising:
a supply node;
a first bootstrap capacitor;
a first active diode circuit including a first n-type Gallium nitride (GaN) transistor coupled to the supply node and the first bootstrap capacitor;
a second bootstrap capacitor;
a second active diode circuit including a second n-type GaN transistor coupled to the supply node and the second bootstrap capacitor;
a pull-up circuit coupled to the first bootstrap capacitor;
a pull-down circuit coupled to the second bootstrap capacitor; and
a third transistor including a gate coupled to the pull-up circuit and the pull-down circuit.

12. The apparatus of claim 11, wherein:
the first active diode circuit includes a first comparator including a first input path coupled to the supply node, a second input path coupled to the first bootstrap capacitor, and an output node coupled to a gate of the first n-type GaN transistor; and
the second active diode circuit includes a second comparator including a first additional input path coupled to the supply node, a second additional input path coupled to the second bootstrap capacitor, and an additional output node coupled to a gate of the second n-type GaN transistor.

13. The apparatus of claim 11, wherein:
the pull-up circuit includes a first additional transistor coupled between the supply node and the gate of the third transistor; and
the pull-down circuit includes a second additional transistor coupled between the gate of the third transistor and a ground connection.

14. The apparatus of claim 11, further comprising:
a first additional bootstrap capacitor;
a first additional active diode circuit including a first additional n-type GaN transistor coupled to the supply node and the first additional bootstrap capacitor;
a second additional bootstrap capacitor;
a second additional active diode circuit including a second additional n-type GaN transistor coupled to the supply node and the second additional bootstrap capacitor;
an additional pull-up circuit coupled to the first additional bootstrap capacitor;
an additional pull-down circuit coupled to the second additional bootstrap capacitor; and
a fourth transistor including a gate coupled to the additional pull-up circuit and the additional pull-down circuit, and a terminal coupled to a terminal of the third transistor.

15. The apparatus of claim 14, further comprising an inductor coupled to the terminal of third transistor and the terminal of the fourth transistor.

16. The apparatus of claim 15, wherein the apparatus comprises a power stage, and wherein:
the third transistor is included in a low-side of the power stage; and
the fourth transistor is included in a high-side transistor of the power stage.

17. The apparatus of claim 14, further comprising:
a first additional capacitor coupled between a voltage node and a ground connection; and
third additional active diode circuit coupled to the supply node and the voltage node.

18. The apparatus of claim 11, wherein the apparatus comprises as system in a package (SiP), the SiP including the first bootstrap capacitor, the first active diode circuit, the second bootstrap capacitor, the second active diode circuit, the pull-up circuit, the pull-down circuit, and the third transistor.

19. A process of making an electronic apparatus, comprising:
forming a bootstrap capacitor; and
forming an active diode circuit, including forming a comparator and an n-type Gallium nitride (GaN) transistor, the comparator including a first input path coupled to a supply node and a second input path coupled to the bootstrap capacitor, and the n-type GaN transistor including a gate coupled to an output node of the comparator.

20. The process of claim 19, wherein forming the comparator and the n-type GaN transistor includes coupling a first terminal of the n-type GaN transistor to the supply node, and coupling a second terminal of the n-type GaN transistor to a plate of the capacitor.
